(19) United States
(12) Patent Application Publication
(10) Pub. No.: US 2026/0020231 A1
(43) Pub. Date: Jan. 15, 2026

(54) SEMICONDUCTOR MEMORY DEVICE

(71) Applicant: Samsung Electronics Co., Ltd., Suwon-si (KR)

(72) Inventors: Dong Sik KONG, Suwon-si (KR); Sung Ho JANG, Suwon-si (KR); Kyul KO, Suwon-si (KR); Ji Hye KWON, Suwon-si (KR); Jun Soo KIM, Suwon-si (KR); Dae Hyun MOON, Suwon-si (KR); Jeong Hoon OH, Suwon-si (KR); Kyung Hwa LEE, Suwon-si (KR); Hyun Seung CHOI, Suwon-si (KR); Dong Gyu HEO, Suwon-si (KR)

(73) Assignee: Samsung Electronics Co., Ltd., Suwon-si (KR)

(21) Appl. No.: 19/252,366

(22) Filed: Jun. 27, 2025

(30) Foreign Application Priority Data
Jul. 12, 2024 (KR) 10-2024-0092423
Mar. 26, 2025 (KR) 10-2025-0038895

(51) Int. Cl. H10B 12/00

(52) U.S. Cl. CPC H10B 12/50; H10B 12/09; H10B 12/315

(57) ABSTRACT

A semiconductor memory device may include a substrate including a cell area and a peripheral area around the cell area, a cell area isolation film within the substrate and separating the cell area and the peripheral area, a cell gate structure within the cell area and the cell area isolation film and including a cell gate electrode extending in a first direction and a cell gate plug on and connected to the cell gate electrode, wherein the cell gate electrode includes a lower cell gate electrode and an upper cell gate electrode stacked in a second direction, and an insertion cell gate film therebetween and including lanthanum (La), the cell gate electrode includes a first region and a second region arranged in the first direction, the insertion cell gate film is included in the first region, and is not included in the second region.

### CROSS-REFERENCE TO RELATED APPLICATION

This application claims priority from Korean Patent Application No. 10-2024-0092423 filed on Jul. 12, 2024, and No. 10-2025-0038895 filed on Mar. 26, 2025 in the Korean Intellectual Property Office, and all the benefits accruing therefrom under 35 U.S.C. 119, the contents of which in its entirety are herein incorporated by reference.

### BACKGROUND

### Technical Field

The present disclosure relates to semiconductor memory devices.

### Description of the Related Art

As semiconductor devices become increasingly integrated, individual circuit patterns are being miniaturized to implement more semiconductor devices in the same area. In other words, as the integration density of semiconductor devices increases, the design rules for semiconductor components decrease. In relatively highly scaled semiconductor devices, the resistance of wordlines increases as their width decreases.

### SUMMARY

Some example embodiments of the present disclosure provide semiconductor memory devices capable of improving reliability and/or performance.

Some example embodiments of the present disclosure also provide methods of manufacturing a semiconductor memory device capable of improving reliability and/or performance.

However, example embodiments of the present disclosure are not restricted to those set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor memory device may include a substrate including a cell area and a peripheral area around the cell area, a cell area isolation film within the substrate and separating the cell area and the peripheral area, a cell gate structure within the cell area and the cell area isolation film, the cell gate structure including a cell gate electrode extending in a first direction and a cell gate plug on and connected to the cell gate electrode, wherein the cell gate electrode includes a lower cell gate electrode and an upper cell gate electrode stacked in a second direction, and an insertion cell gate film between the lower cell gate electrode and the upper cell gate electrode, the insertion cell gate film includes lanthanum (La), the cell gate electrode includes a first region and a second region arranged in the first direction, the first region of the cell gate electrode includes the insertion cell gate film, and the second region of the cell gate electrode does not include the insertion cell gate film.

According to an example embodiment of the present disclosure, a semiconductor memory device may include a substrate including a cell area and a peripheral area around the cell area, a cell area isolation film within the substrate and separating the cell area and the peripheral area, a cell gate structure within the cell area and the cell area isolation film, the cell gate structure including a cell gate electrode extending in a first direction and a cell gate plug on and connected to the cell gate electrode, wherein the cell gate electrode includes a lower cell gate electrode and an upper cell gate electrode stacked in a second direction, and an insertion cell gate film between the lower cell gate electrode and the upper cell gate electrode, the insertion cell gate film includes lanthanum (La), and the cell gate plug does not overlap the insertion cell gate film in the second direction.

According to an example embodiment of the present disclosure, a semiconductor memory device may include a substrate including a cell area and a peripheral area around the cell area, a cell area isolation film within the substrate and separating the cell area and the peripheral area, a cell gate structure including a cell gate trench extending in a first direction within the cell area and the cell area isolation film, and a cell gate electrode within the cell gate trench and a cell gate plug on and connected to the cell gate electrode, wherein the cell gate trench includes long sidewalls extending in the first direction and short sidewalls extending in a second direction perpendicular to the first direction, the cell gate electrode includes a lower cell gate electrode and an upper cell gate electrode stacked in a third direction perpendicular to the first and second directions, and an insertion cell gate film between the lower cell gate electrode and the upper cell gate electrode, the insertion cell gate film includes lanthanum (La), and the insertion cell gate film is on the long sidewalls of the cell gate trench and not on the short sidewalls of the cell gate trench.

According to an example embodiment of the present disclosure, a method of manufacturing a semiconductor memory device comprising forming a cell gate trench in a substrate including a cell region and a cell region isolation film, forming a cell gate insulating film along sidewalls and a bottom surface of the cell gate trench, forming a lower cell gate electrode on the cell gate insulating film to partially fill the cell gate trench, forming a first pre-insertion gate film along an upper surface of the lower cell gate electrode, the sidewalls of the cell gate trench, an upper surface of the substrate, and an upper surface of the cell region isolation film, the first pre-insertion gate film including lanthanum (La), forming a mask pattern on the first pre-insertion gate film, forming a second pre-insertion gate film on the lower cell gate electrode by patterning the first pre-insertion gate film using the mask pattern as a mask, the second pre-insertion gate film exposing a portion of the upper surface of the lower cell gate electrode, removing the mask pattern and forming an upper cell gate film on the second pre-insertion gate film and forming an upper cell gate electrode in the cell gate trench by removing a portion of the upper cell gate film.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail some example embodiments thereof with reference to the attached drawings, in which:

FIG. 1 is a schematic layout view of a semiconductor memory device according to some example embodiments.

FIG. 2 is a layout view of a region R1 of FIG. 1.

FIG. 3 is a layout view illustrating word lines and cell active areas of FIG. 2.

FIG. 4 is a schematic plan view of a region R2 of FIG. 1

FIGS. 5 to 8 are cross-sectional views taken along lines A-A, B-B, C-C, and D-D of FIG. 4, respectively.

FIG. 9 is a diagram illustrating cell gate electrodes of FIG. 4.

FIG. 10 is a diagram illustrating a concentration of lanthanum element in the cell gate electrodes of FIG. 4.

FIGS. 11 to 13 are diagrams illustrating a semiconductor memory device according to some example embodiments.

FIGS. 14 and 15 are diagrams illustrating a semiconductor memory device according to some example embodiments, respectively.

FIGS. 16 to 18 are diagrams illustrating a semiconductor memory device according to some example embodiments, respectively.

FIGS. 19 and 20 are diagrams illustrating a semiconductor memory device according to some example embodiments.

FIG. 21 is a diagram illustrating a semiconductor memory device according to some example embodiments.

FIGS. 22 to 30 are diagrams of intermediate structures corresponding to intermediate steps of a method for fabricating a semiconductor memory device according to some example embodiments.

### DETAILED DESCRIPTION

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

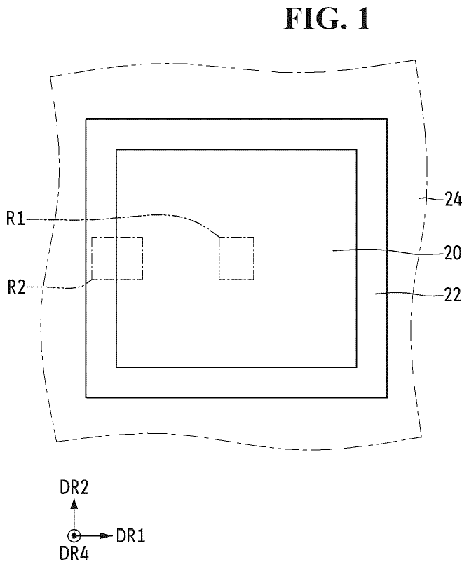

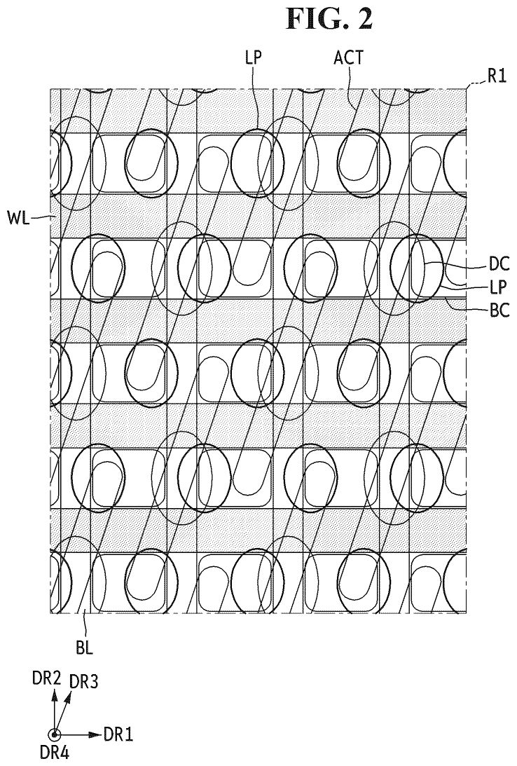

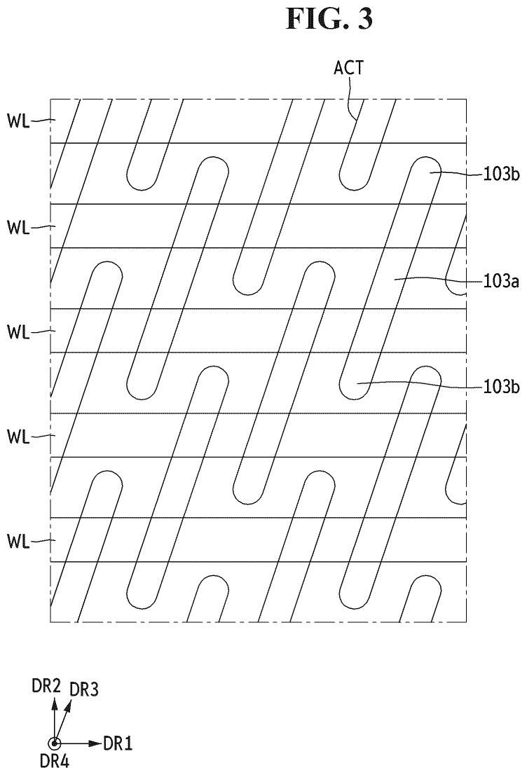

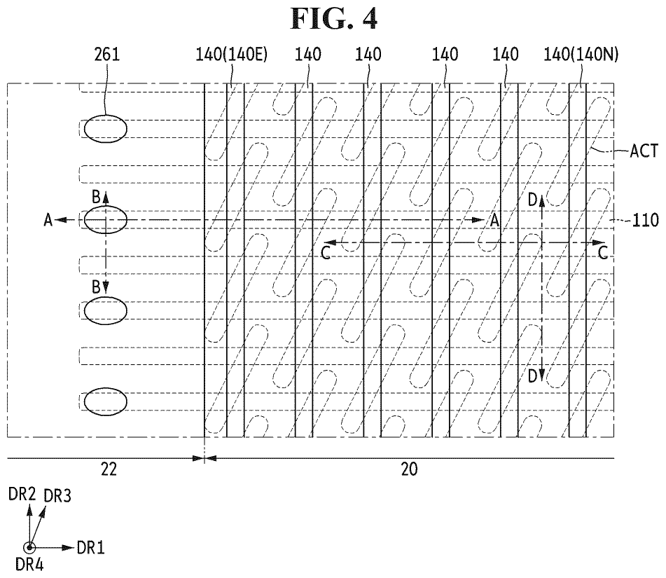

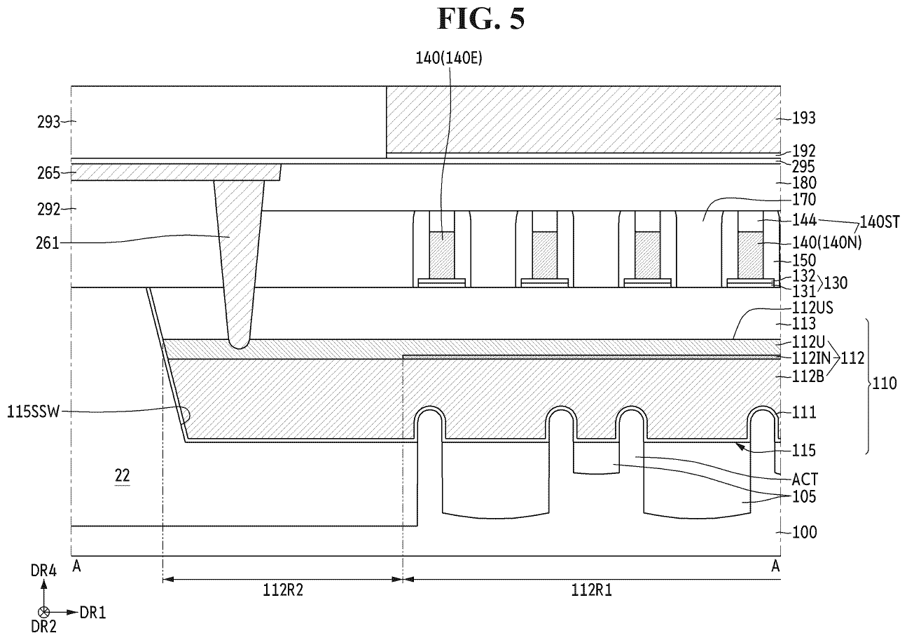

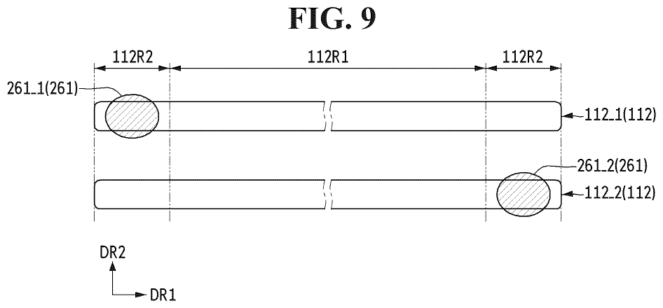

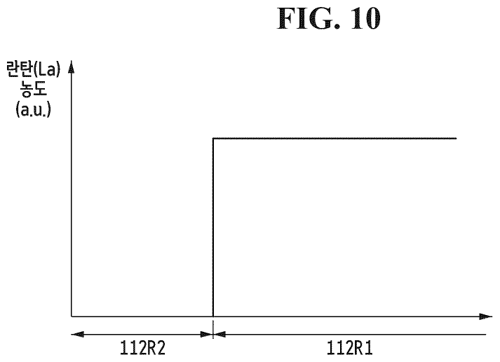

FIG. 1 is a schematic layout view of a semiconductor memory device according to some example embodiments of the present disclosure. FIG. 2 is a layout view of a region R1 of FIG. 1. FIG. 3 is a layout view illustrating wordlines and cell active areas of FIG. 2. FIG. 4 is a schematic plan view of a region R2 of FIG. 1. FIGS. 5 to 8 are cross-sectional views taken along lines A-A, B-B, C-C, and D-D of FIG. 4, respectively. FIG. 9 is a diagram illustrating each cell gate electrode in FIG. 4. FIG. 10 is a diagram illustrating a concentration of lanthanum element in the cell gate electrodes of FIG. 4.

For reference, FIG. 4 illustrates only cell active areas ACT, cell gate structures 110, cell conductive lines 140, and cell gate plugs 261.

A dynamic random-access memory (DRAM) is illustrated as an example semiconductor memory device, but example embodiments of the present disclosure are not limited thereto.

Referring to FIGS. 1 to 4 and 9, the semiconductor memory device according to an example embodiment of the present disclosure may include a cell area 20, a cell area isolation film 22, and a peripheral area 24.

The cell area isolation film 22 may be disposed along the perimeter of the cell area 20. The cell area isolation film 22 may separate the cell area 20 from the peripheral area 24. The cell area 20 may be defined by the cell area isolation film 22. The peripheral area 24 may be defined around the cell area 20.

The cell area 20 may include a plurality of cell active areas ACT. The cell active areas ACT may be defined by a cell element isolation film 105 in FIGS. 5, 7, and 8, which is formed within a substrate 100 in FIGS. 5 to 8. As the design rules of the semiconductor memory device decrease, the cell active areas ACT may be arranged as diagonal or oblique bars according to some example embodiments of the present disclosure. For example, the cell active areas ACT may extend in a third direction DR3.

A plurality of gate electrodes extending in a first direction DR1 across the cell active areas ACT may be disposed. These gate electrodes may extend in parallel to one another. For example, the gate electrodes may be wordlines WL. The wordlines WL may be arranged at equal intervals. The width of the wordlines WL or the spacing between the wordlines WL may be determined according to the design rules. The conductive lines included in cell gate structures 110 may be the wordlines WL.

For example, the wordlines WL may extend to the cell area isolation film 22. Portions of the wordlines WL may overlap the cell area isolation film 22 in a fourth direction DR4.

Each of the cell active areas ACT may be divided into three parts by two wordlines WL extending in a first direction D1. Each of the cell active areas ACT may include a bitline connection area 103a and storage connection areas 103b. The bitline connection areas 103a may be located in the middle of the respective cell active areas ACT, and the storage connection areas 103b may be located at the ends of the respective cell active areas ACT.

A plurality of bitlines BL extending in a second direction DR2, which intersects the wordlines WL, may be disposed on the wordlines WL. The bitlines BL may extend in parallel to one another. The bitlines BL may be disposed at equal intervals. The width of the bitlines BL or the spacing between the bitlines BL may be determined according to the design rules.

Although not illustrated, bitlines BL may extend to the cell area isolation film 22. Portions of the bitlines BL may overlap the cell area isolation film 22 in the fourth direction DR4. The fourth direction DR4 may be orthogonal to the first direction DR1, the second direction DR2, and the third direction DR3. The fourth direction DR4 may be the thickness direction of the substrate 100. The first direction DR1 may be orthogonal to the second direction DR2. The third direction DR3 may form an arbitrary angle with respect to the first direction DR1 and the second direction DR2.

The bitlines BL may include cell conductive lines 140. The cell conductive lines 140 may include normal cell conductive lines 140N and edge cell conductive lines 140E. For example, the edge cell conductive lines 140E may be the cell conductive line disposed at an outermost edge among the cell conductive lines 140.

The width, in the first direction DR1, of the edge cell conductive lines 140E is illustrated as being the same as the width of the normal cell conductive lines 140N in the first direction DR1, but example embodiments of the present disclosure are not limited thereto. In some example embodiments, contrary to what is illustrated, the width, in the first direction DR1, of the edge cell conductive lines 140E may be greater than the width, in the first direction DR1, of the normal cell conductive lines 140N.

The semiconductor memory device according to some example embodiments of the present disclosure may include various contact arrangements formed on the cell active areas ACT. The various contact arrangements may include, for example, direct contacts DC, buried contacts BC, and landing pads LP.

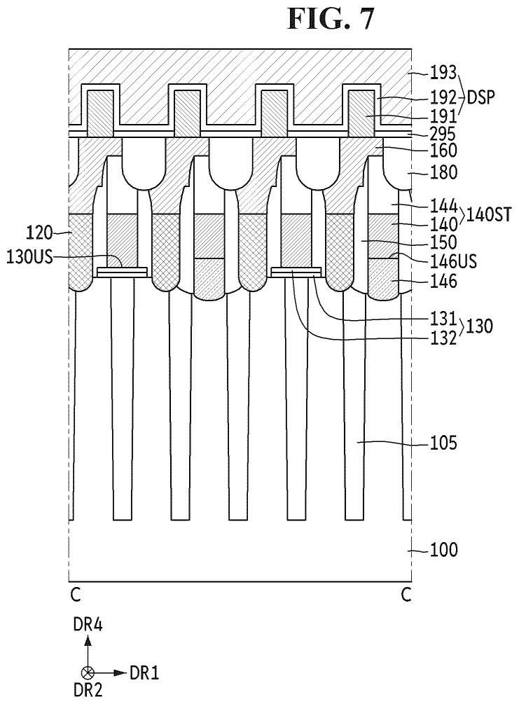

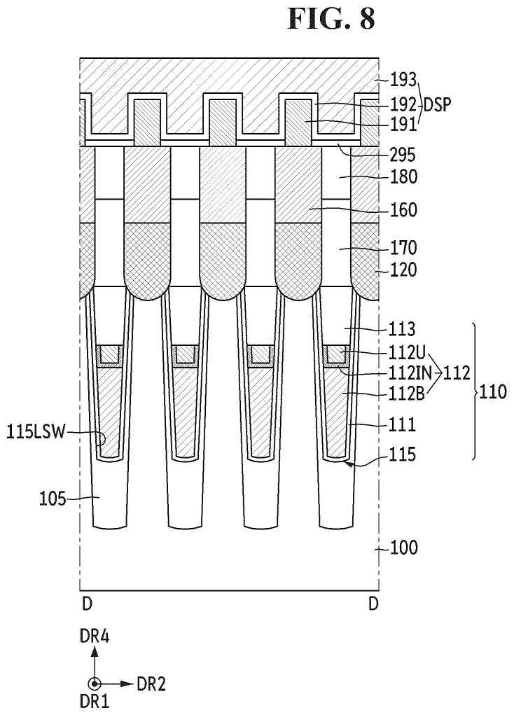

Here, the direct contacts DC may refer to contacts that electrically connect the cell active areas ACT to the bitlines BL, and the buried contacts BC may refer to contacts that connect the cell active areas ACT to the lower electrodes of data storage patterns 191 in FIGS. 7 and 8. The contact area between the buried contacts BC and the cell active areas ACT may be relatively small. Accordingly, the conductive landing pads LP may be provided to enlarge the contact area with the lower electrodes 191 or to enlarge the contact area with the cell active areas ACT.

The landing pads LP may be disposed between the cell active areas ACT and the buried contacts BC, or between the buried contacts BC and the lower electrodes 191. In the semiconductor memory device according to some example embodiments of the present disclosure, the landing pads LP may be disposed between the buried contacts BC and the lower electrodes of data storage patterns DSP. As the landing pads LP are introduced to enlarge the contact areas, the contact resistance between the cell active areas ACT and the lower electrodes of capacitors can be reduced.

The direct contacts DC may be connected to the bitline connection areas 103a. The buried contacts BC may be connected to the storage connection areas 103b. As the buried contacts BC are arranged at both ends of the cell active areas ACT, the landing pads LP may be arranged adjacent to both ends of the cell active areas ACT to partially overlap the buried contacts BC. In other words, the buried contacts BC may be formed to overlap the cell active areas ACT, which are between the wordlines WL and between the bitlines BL, and the cell element isolation film 105.

The wordlines WL may be formed in a buried structure within the substrate 100. The wordlines WL may be disposed across the cell active areas ACT between the direct contacts DC or the buried contacts BC. As illustrated, two wordlines WL may be arranged across one cell active area ACT. As the cell active areas ACT extend across the cell active areas ACT along the third direction DR3, the wordlines WL may form an angle of less than 90 degrees with the cell active areas ACT.

The direct contacts DC and the buried contacts BC may be symmetrically arranged. Thus, the direct contacts DC and the buried contacts BC may be arranged in straight lines along the first direction DR1 and the second direction DR2.

Meanwhile, the landing pads LP, unlike the direct contacts DC and the buried contacts BC, may be arranged in a zigzag pattern in the second direction DR2, which is the direction in which the bitlines BL extend. Additionally, in the first direction DR1, which is an extension direction of the wordlines WL, the landing pads LP may overlap the same sides of the respective bitlines BL.

For example, landing pads LP in a first line (e.g., a first row) may overlap the left side of their corresponding bitline BL, and landing pads LP in a second line (e.g., a second row) may overlap the right side of their corresponding bitline BL.

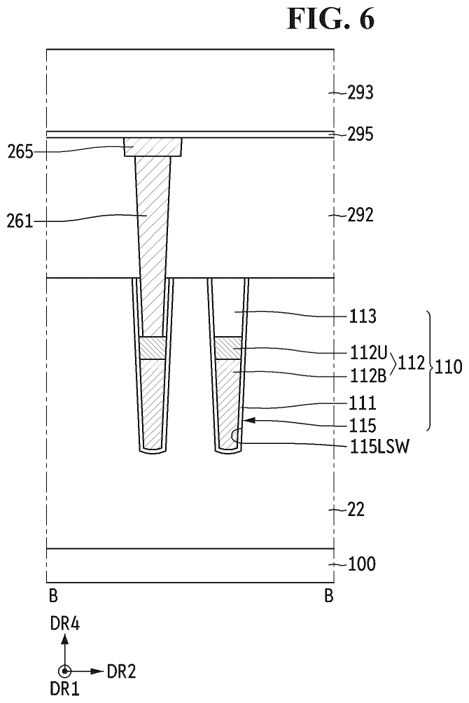

A plurality of cell gate plugs 261 may be disposed on the cell gate structures 110. The cell gate plugs 261 may be connected to the cell gate structures 110. For example, the cell gate plugs 261 may be connected to cell gate electrodes 112 in FIGS. 5 and 6, which are included in the cell gate structures 110.

The cell gate plugs 261 may be connected to the cell gate electrodes 112 near the ends of the cell gate structures 110 (e.g., near the ends of the wordlines WL).

Referring to FIGS. 1 to 10, the semiconductor memory device according to some example embodiments of the present disclosure may include the cell active areas ACT, the cell gate structures 110, the cell conductive lines 140, storage pads 160, the data storage patterns DSP, and the cell gate plugs 261.

The substrate 100 may include the cell area 20, the cell area isolation film 22, and the peripheral area 24. The substrate 100 may be a silicon substrate or a silicon-on-insulator (SOI) substrate. For example, the substrate 100 may include silicon-germanium (SiGe), SiGe-on-insulator (SGOI), indium antimonide, a lead telluride compound, indium arsenide, indium phosphide, gallium arsenide, or gallium antimonide, but example embodiments of the present disclosure are not limited thereto.

The cell gate structures 110, a plurality of bitline structures 140ST, the storage pads 160, and the data storage patterns DSP may be disposed in the cell area 20.

The cell element isolation film 105 may be formed within the substrate 100 of the cell area 20. The cell element isolation film 105 may have a shallow trench isolation (STI) structure with relatively good isolation characteristics. The cell area isolation film 22, like the cell element isolation film 105, may have an STI structure.

The cell element isolation film 105 may define the cell active areas ACT within the cell area 20. The cell active areas ACT defined by the cell element isolation film 105 may have a long island shape including a minor axis and a major axis, as illustrated in FIGS. 2 to 4.

The cell active areas ACT may have an oblique line shape forming an angle of less than 90 degrees with respect to the wordlines WL, which are disposed within the cell element isolation film 105. The cell active areas ACT may have an oblique line shape forming an angle of less than 90 degrees with respect to the bitlines BL, which are formed on the cell element isolation film 105.

In other words, the cell active areas ACT may have an oblique line shape forming an angle of less than 90 degrees with respect to the cell gate structures 110, which are disposed within the cell element isolation film 105. The cell active areas ACT may have an oblique line shape forming an angle of less than 90 degrees with respect to the bitline structures 140ST, which are formed on the cell element isolation film 105.

The depth from the upper surface of the cell area isolation film 22 to the lowermost part of the cell area isolation film 22 is illustrated as being the same as the depth from the upper surface of the cell area isolation film 22 to the lowermost part of the cell element isolation film 105, but example embodiments of the present disclosure are not limited thereto. In some example embodiments, contrary to what is illustrated, the depth from the upper surface of the cell area isolation film 22 to the lowermost part of the cell area isolation film 22 may be different from the depth from the upper surface of the cell area isolation film 22 to the lowermost part of the cell element isolation film 105.

Each of the cell element isolation film 105 and the cell area isolation film 22 may include, for example, at least one of a silicon oxide film, a silicon nitride film, or a silicon oxynitride film, but example embodiments of the present disclosure are not limited thereto. In FIGS. 5 to 8, each of the cell element isolation film 105 and the cell area isolation film 22 is illustrated as being formed of a single insulating film, but example embodiments of the present disclosure are not limited thereto. Depending on the width of the cell element isolation film 105 and the cell area isolation film 22, each of the cell element isolation film 105 and the cell area isolation film 22 may be formed of a single insulating film or multiple insulating films.

In FIG. 7, the upper surface of the cell element isolation film 105 and the upper surface of the substrate 100 are illustrated as being on the same plane, but example embodiments of the present disclosure are not limited thereto.

A plurality of cell gate structures 110 may be disposed within the cell area 20 and the cell area isolation film 22. In the cell area 20, each of the cell gate structures 110 may be formed within the substrate 100 and the cell element isolation film 105. The cell gate structures 110 may be formed across the cell active areas ACT defined by the cell element isolation film 105 and the cell element isolation film 105. Portions of the cell gate structures 110 may be disposed within the cell area isolation film 22.

The cell gate structures 110 may extend in the first direction DR1. The cell gate structures 110 may be spaced apart in the second direction DR2. The cell gate structures 110 may include cell gate trenches 115, cell gate insulating films 111, cell gate electrodes 112, and cell gate capping patterns 113, which are all disposed within the substrate 100 and the cell element isolation film 105. Here, the cell gate electrodes 112 may correspond to the wordlines WL.

The cell gate trenches 115 may be disposed within the cell area 20 and the cell area isolation film 22. The cell gate trenches 115 may extend in the first direction DR1. In the cell area 20, the cell gate trenches 115 may be disposed within the substrate 100 and the cell element isolation film 105.

Each of the cell gate trenches 115 may include long sidewalls 115LSW, which extend in the first direction DR1, and short sidewalls 115SSW, which extend in the second direction DR2. The short sidewalls 115SSW of the cell gate trenches 115 may connect the long sidewalls 115LSW of the cell gate trenches 115 that are spaced apart in the second direction DR2. Because the ends of the cell gate structures 110 are disposed within the cell area isolation film 22, the short sidewalls 115SSW of the cell gate trenches 115 may be defined by the cell area isolation film 22. Each of the cell gate structures 110 may include first and second ends that are spaced apart in the first direction DR1.

The bottom surfaces of the cell gate trenches 115 may be curved. The cell gate trenches 115 may be relatively deep within the cell element isolation film 105 and relatively shallow within the cell active areas ACT. That is, the depth of the cell gate trenches 115 within the cell element isolation film 105 may be greater than the depth of the cell gate trenches 115 within the cell active areas ACT.

The cell gate insulating films 111 may extend along the long sidewalls 115LSW of the cell gate trenches 115, the short sidewalls 115SSW of the cell gate trenches 115, and the bottom surfaces of the cell gate trenches 115. The cell gate insulating films 111 may extend along at least part of the profile of the cell gate trenches 115. The cell gate insulating films 111 may include, for example, at least one of silicon oxide, silicon nitride, silicon oxynitride, or a high-k material with a higher dielectric constant than silicon oxide. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof.

The cell gate electrodes 112 may be disposed on the cell gate insulating films 111. The cell gate electrodes 112 may fill portions of the cell gate trenches 115.

The cell gate electrodes 112 may include lower cell gate electrodes 112B and upper cell gate electrodes 112U that are stacked in the fourth direction DR4. The cell gate electrodes 112 may include insertion cell gate films 112IN that are disposed between the lower cell gate electrodes 112B and the upper cell gate electrodes 112U.

The lower cell gate electrodes 112B and the upper cell gate electrodes 112U may extend in the first direction DR1. The insertion cell gate films 112IN may extend in the first direction DR1. The upper cell gate electrodes 112U may include upper surfaces 112US of the cell gate electrodes 112.

The lower cell gate electrodes 112B and the upper cell gate electrodes 112U may include a conductive material. For example, the lower cell gate electrodes 112B and the upper cell gate electrodes 112U may include at least one of conductive metal nitride, conductive metal silicon nitride, metal carbonitride, conductive metal silicide, conductive metal oxide, a two-dimensional (2D) material, or metal.

The lower cell gate electrodes 112B and the upper cell gate electrodes 112U may include at least one of titanium nitride (TiN), tungsten (W), or molybdenum (Mo), but example embodiments of the present disclosure are not limited thereto. In the semiconductor memory device according to some example embodiments of the present disclosure, the lower cell gate electrodes 112B and/or the upper cell gate electrodes 112U may have a single conductive film structure. The lower cell gate electrodes 112B and the upper cell gate electrodes 112U may both have a single film structure. For example, the lower cell gate electrodes 112B and the upper cell gate electrodes 112U may both have a single conductive film structure.

The insertion cell gate films 112IN may include La. For example, the insertion cell gate films 112IN may include lanthanum oxide (LaO). Here, the chemical formula “LaO” represents the elements included in the corresponding compound but does not necessarily indicate the stoichiometric relationship between these elements.

In another example, the insertion cell gate films 112IN may include metal doped with La or a metal compound doped with La. For example, the metal compound may include at least one of metal nitride, metal oxynitride, or metal oxide. The metal included in the metal compound may be the metal included in the lower cell gate electrodes 112B and/or the upper cell gate electrodes 112U.

For example, the lower cell gate electrode 112B and the upper cell gate electrode 112U may include titanium nitride. In this example, the insertion cell gate films 112IN may include one of a La-doped titanium nitride, a La-doped titanium oxynitride, or a La-doped titanium oxide.

For example, the lower cell gate electrodes 112B may include titanium nitride, and the upper cell gate electrodes 112U may include Mo. In this case, the insertion cell gate films 112IN may include at least one of La-doped titanium nitride, La-doped titanium oxynitride, La-doped titanium oxide, La-doped Mo, or La-doped molybdenum oxide.

Because the insertion cell gate film 112IN may include metal doped La or a metal compound doped with La, the boundaries between the insertion cell gate films 112IN and the lower cell gate electrodes 112B may not be clearly distinct. Similarly, the boundaries between the insertion cell gate films 112IN and the upper cell gate electrodes 112U may not be clearly distinct.

Each of the cell gate electrodes 112 may include a first region 112R1 and second regions 112R2. For example, the second regions 112R2 of each of the cell gate electrodes 112 may be disposed on both sides of the first region 112R1 of the corresponding cell gate electrode 112.

The first region 112R1 and the second regions 112R2 of each of the cell gate electrodes 112 may be arranged in the first direction DR1. The second regions 112R2 of each of the cell gate electrodes 112 may be disposed on both sides, in the first direction DR1, of the first region 112R1 of the corresponding cell gate electrode 112.

In some example embodiments, contrary to what is illustrated, the second regions 112R2 of each of the cell gate electrodes 112 may not be disposed on both sides of the first region 112R1 of the corresponding cell gate electrode 112. The second regions 112R2 of each of the cell gate electrodes 112 may be disposed on a first side of the first region 112R1 of the corresponding cell gate electrode 112, but not on a second side of the first region 112R1 of the corresponding cell gate electrode 112. In this case, the cell gate plugs 261 may be disposed on the first sides of the first regions 112R1 of the cell gate electrodes 112, but not on the second sides of the first regions 112R1 of the cell gate electrodes 112. In other words, the second regions 112R2 of each of the cell gate electrodes 112 may be positioned where their corresponding cell gate plug 261 is landed.

The first regions 112R1 of the cell gate electrodes 112 may include the insertion cell gate films 112IN. The second regions 112R2 of the cell gate electrodes 112 may not include the insertion cell gate films 112IN. In other words, the second region 112R2 of the cell gate electrodes 112 may not include the insertion cell gate films 112IN. Referring to FIG. 10, the first regions 112R1 of the cell gate electrodes 112 may include La, and the second regions 112R2 of the cell gate electrodes 112 may not include La.

The second regions 112R2 of the cell gate electrodes 112 may overlap the cell area isolation film 22 in the fourth direction DR4. In the semiconductor memory device according to some example embodiments of the present disclosure, at least portions of the second regions 112R2 of the cell gate electrodes 112 may be disposed within the cell area isolation film 22. At least portions of the second regions 112R2 of the cell gate electrodes 112 may overlap the cell area isolation film 22 in the fourth direction DR4.

The second regions 112R2 of the cell gate electrodes 112 are illustrated as not overlapping the cell area 20 in the fourth direction DR4, but example embodiments of the present disclosure are not limited thereto. In some example embodiments, contrary to what is illustrated, portions of the second regions 112R2 of the cell gate electrodes 112 may overlap the cell active areas ACT included in the cell area 20 in the fourth direction DR4.

Because the ends of the cell gate structures 110 are disposed within the cell area isolation film 22, the ends of the cell gate electrodes 112 may be disposed within the cell area isolation film 22. In the semiconductor memory device according to some example embodiments of the present disclosure, the second regions 112R2 of the cell gate electrodes 112 may include the ends of the cell gate electrodes 112. Because the second regions 112R2 of the cell gate electrodes 112 are disposed near the ends of the cell gate electrodes 112, the insertion cell gate films 112IN may not extend along the short sidewalls 115SSW of the cell gate trenches 115.

In the second regions 112R2 of the cell gate electrodes 112, the insertion cell gate films 112IN may not extend along the long sidewalls 115LSW of the cell gate trenches 115. Because the first regions 112R1 of the cell gate electrodes 112 include the insertion cell gate films 112IN, the insertion cell gate films 112IN may extend along the long sidewalls 115LSW of the cell gate trenches 115 in the first regions 112R1 of the cell gate electrodes 112. The insertion cell gate films 112IN may be disposed on portions of the long sidewalls 115LSW of the cell gate trenches 115 extending in the first direction DR1.

In the first regions 112R1 of the cell gate electrodes 112, the insertion cell gate films 112IN may extend along the upper surfaces of the lower cell gate electrodes 112B.

Because the insertion cell gate films 112IN include La, the work function of transistors with the first regions 112R1 of the cell gate electrodes 112 as their gate electrodes may be adjusted. Accordingly, the performance and/or reliability of the semiconductor memory device according to some example embodiments of the present disclosure can be improved.

For example, some of the bitlines BL included in the semiconductor memory device according to some example embodiments of the present disclosure may be dummy bitlines that are not used in the actual operation of memory cells. That is, some of the memory cells included in the semiconductor memory device according to some example embodiments of the present disclosure may be dummy memory cells. The other memory cells included in the semiconductor memory device according to some example embodiments of the present disclosure may be normal memory cells that actually operate.

For example, the edge cell conductive lines 140E may be included in the dummy bitlines. In one example, the normal cell conductive lines 140N may not be used as dummy bitlines. In another example, some of the normal cell conductive lines 140N adjacent to the edge cell conductive lines 140E may be included in the dummy bitlines. The first regions 112R1 of the cell gate electrodes 112 may be disposed in the portions of the cell gate electrodes 112 that operate the normal memory cells.

The insertion cell gate films 112IN, which adjust the work function of transistors, may increase the resistance of the cell gate electrodes 112. That is, if the insertion cell gate films 112IN are fully disposed between the lower cell gate electrodes 112B and the upper cell gate electrodes 112U, the resistance of the cell gate electrodes 112 may increase.

However, in the second regions 112R2 of the cell gate electrodes 112 where the insertion cell gate films 112IN are not disposed, the lower cell gate electrodes 112B and the upper cell gate electrodes 112U may be directly connected. In other words, as the cell gate electrodes 112 include the second regions 112R2 that do not include the insertion cell gate films 112IN, the increase in the resistance of the cell gate electrodes 112 can be reduced or prevented. Accordingly, the performance and/or reliability of the semiconductor memory device according to some embodiments of the present disclosure can be improved.

The cell gate capping patterns 113 may be disposed on the cell gate electrodes 112. The cell gate capping patterns 113 may extend along the upper surfaces 112US of the cell gate electrodes 112. The cell gate capping patterns 113 may fill the cell gate trenches 115 that remain after the formation of the cell gate electrodes 112 and the cell gate insulating films 111. The cell gate insulating films 111 are illustrated as extending along the sidewalls of the cell gate capping pattern 113, but example embodiments of the present disclosure are not limited thereto.

The cell gate capping patterns 113 include or define the upper surfaces of the cell gate structures 110. The upper surfaces of the cell gate capping patterns 113 may be the upper surfaces of the cell gate structures 110. The cell gate capping patterns 113 may be formed of an insulating material. The cell gate capping patterns 113 may include, for example, at least one of silicon nitride, silicon oxynitride, silicon oxide, silicon carbonitride, silicon oxycarbonitride, or a combination thereof.

The cell gate structures 110 may not include a semiconductor material film disposed between the cell gate electrodes 112 and the cell gate capping patterns 113. If the cell gate structures 110 include a semiconductor material film, the resistance of the cell gate structures 110 may increase. As the cell gate structures 110 do not include a semiconductor material film, the resistance of the conductive material patterns included in the cell gate structure 110 may decrease. Accordingly, the performance and/or reliability of the semiconductor memory device according to some example embodiments of the present disclosure can be improved.

Although not illustrated, impurity doping regions may be formed on at least one side of each of the cell gate structures 110. The impurity doping regions may be the source/drain regions of transistors. The impurity doping regions may be formed in the storage connection areas 103b and the bitline connection areas 103a of FIG. 3.

The bitline structures 140ST may include the cell conductive lines 140 and cell line capping films 144. The bitline structures 140ST may include the normal cell conductive lines 140N and the cell line capping films 144. The bitline structures 140ST, which are disposed at the outermost parts of the cell area 20, may include the edge cell conductive lines 140E. The cell conductive lines 140 may be disposed on the substrate 100 and the cell element isolation film 105 where the cell gate structures 110 are disposed.

The cell conductive lines 140 may extend in the second direction DR2. The cell conductive lines 140 may intersect the cell element isolation film 105 and the cell active areas ACT defined by the cell element isolation film 105. Here, the cell conductive lines 140 may correspond to the bitlines BL.

The cell conductive lines 140 may include, for example, at least one of a doped semiconductor material, a conductive silicide compound, conductive metal nitride, a 2D material, or metal. In the semiconductor memory device according to some example embodiments of the present disclosure, the 2D material may be a metallic material and/or a semiconductor material. The 2D material may include a 2D allotrope or a 2D compound. For example, the 2D material may include, for example, at least one of graphene, molybdenum disulfide (MoS₂), molybdenum diselenide (MoSe₂), tungsten diselenide (WSe₂), or tungsten disulfide (WS₂), but example embodiments of the present disclosure are not limited thereto. That is, these 2D materials are merely examples, and thus, the type of 2D material that can be included in the semiconductor memory device according to some example embodiments of the present disclosure is not particularly limited thereto.

The cell conductive lines 140 are illustrated as being single films, but example embodiments of the present disclosure are not limited thereto. In some example embodiments, contrary to what is illustrated, the cell conductive lines 140 may include a plurality of conductive films conductive materials stacked.

The cell line capping films 144 may be disposed on the cell conductive lines 140. The cell line capping films 144 may extend in the second direction DR2 along the upper surfaces of the cell conductive lines 140. The cell line capping films 144 may include, for example, at least one of silicon nitride, silicon oxynitride, silicon carbonitride, or silicon oxycarbonitride. In the semiconductor memory device according to some example embodiments of the present disclosure, the cell line capping films 144 may include silicon nitride. The cell line capping films 144 are illustrated as being single films, but example embodiments of the present disclosure are not limited thereto.

Bitline contacts 146 may be disposed between the cell conductive lines 140 and the substrate 100. That is, the cell conductive lines 140 may be disposed on the bitline contacts 146. For example, the bitline contacts 146 may be disposed where the cell conductive lines 140 intersect the middle parts of the cell active areas ACT, which have a long island shape. The bitline contacts 146 may be disposed between the bitline connection areas 103a of the cell active areas ACT and the cell conductive lines 140. The bitline contacts 146 may be connected to the bitline connection areas 103a.

A plurality of bitline contacts 146 may be disposed along the second direction DR2. The cell conductive lines 140 may be disposed on the plurality of bitline contacts 146 and may extend in the second direction DR2.

The bitline contacts 146 may electrically connect the cell conductive lines 140 and the substrate 100. Here, the bitline contacts 146 may correspond to the direct contacts DC. The bitline contacts 146 may include, for example, at least one of a doped semiconductor material, a conductive silicide compound, conductive metal nitride, or metal.

Referring to FIG. 7, the thickness of the cell conductive lines 140 in the areas overlapping upper surfaces 146US of the bitline contacts 146 may be less than the thickness of the cell conductive lines 140 in the areas not overlapping the upper surfaces 146US of the bitline contacts 146. In some example embodiments, contrary to what is illustrated, the thickness of the cell conductive lines 140 in the areas overlapping upper surfaces 146US of the bitline contacts 146 may be the same as the thickness of the cell conductive lines 140 in the areas not overlapping the upper surfaces 146US of the bitline contacts 146.

Cell insulating films 130 may be disposed on the substrate 100 and the cell element isolation film 105. For example, the cell insulating films 130 may be disposed on the substrate 100 and the cell element isolation film 105, where the bitline contacts 146 are not formed. The cell insulating films 130 may be disposed between the substrate 100 and the cell conductive lines 140, and between the cell element isolation film 105 and the cell conductive lines 140. In the semiconductor memory device according to some example embodiments of the present disclosure, the upper surfaces 146US of the bitline contacts 146 may be higher than upper surfaces 130US of the cell insulating films 130 based on the upper surface of the substrate 100.

The cell insulating films 130 may be single films. In some example embodiments, as illustrated, the cell insulating films 130 may also be multilayer films including first cell insulating films 131 and second cell insulating films 132. For example, the first cell insulating films 131 may each include a silicon oxide film, and the second cell insulating films 132 may each include a silicon nitride film. However, example embodiments of the present disclosure are not limited to this example. In some other example embodiments, contrary to what is illustrated, the cell insulating films 130 may each include three or more insulating films.

Cell line spacers 150 may be disposed on the sidewalls of the cell conductive lines 140 and the cell line capping films 144. In parts of the cell conductive lines 140 where the bitline contacts 146 are formed, the cell line spacers 150 may be formed on the substrate 100 and the cell element isolation film 105. The cell line spacers 150 may be disposed on the sidewalls of the cell conductive lines 140, the sidewalls of the cell line capping films 144, and the sidewalls of the bitline contacts 146.

In parts of the cell conductive lines 140 where the bitline contacts 146 are not formed, the cell line spacers 150 may be disposed on the cell insulating films 130. The cell line spacers 150 may be disposed on the sidewalls of the cell conductive lines 140 and the sidewalls of the cell line capping films 144.

The cell line spacers 150 are illustrated as being single films, but example embodiments of the present disclosure are not limited thereto. In some example embodiments, contrary to what is illustrated, the cell line spacers 150 may have a multilayer structure. The cell line spacers 150 may include, for example, at least one of a silicon oxide film, a silicon nitride film, a silicon oxynitride film, a silicon oxycarbonitride film, air, or a combination thereof, but example embodiments of the present disclosure are not limited thereto.

Fence patterns 170 may be disposed on the substrate 100 and the cell element isolation film 105. The fence patterns 170 may be disposed to overlap the cell gate structures 110, which are formed in the substrate 100 and the cell element isolation film 105. The fence patterns 170 may be disposed on the cell gate capping patterns 113.

The fence patterns 170 may be disposed between the bitline structures 140ST extending in the second direction DR2. The fence patterns 170 may include, for example, at least one of silicon oxide, silicon nitride, silicon oxynitride, or a combination thereof.

A plurality of storage contacts 120 may be disposed between the cell conductive lines 140 adjacent in the first direction DR1. The storage contacts 120 may be disposed between the fence patterns 170 adjacent in the second direction DR2. The storage contacts 120 may overlap in the fourth direction DR4 with the substrate 100 and the cell element isolation film 105, between the cell conductive lines 140. The storage contacts 120 may be connected to the storage connection areas 103b of the cell active areas ACT. Here, the storage contacts 120 may correspond to the buried contacts BC.

The storage contacts 120 may include, for example, at least one of a doped semiconductor material, a conductive silicide compound, conductive metal nitride, or metal.

The storage pads 160 may be disposed on the storage contacts 120, respectively. The storage pads 160 may be electrically connected to the storage contacts 120. The storage pads 160 may be connected to the storage connection areas 103b of the cell active areas ACT. Here, the storage pads 160 may correspond to the landing pads LP.

The storage pads 160 may overlap portions of the upper surfaces of the cell conductive lines 140. The storage pads 160 may include, for example, at least one of a doped semiconductor material, a conductive silicide compound, conductive metal nitride, conductive metal carbide, or metal.

A pad isolation insulating film 180 may be disposed on the storage pads 160 and the cell conductive lines 140. For example, the pad isolation insulating film 180 may be disposed on the cell line capping films 144. The pad isolation insulating film 180 may define the storage pads 160 that form a plurality of isolated regions. The pad isolation insulating film 180 may not cover the upper surfaces of the storage pads 160. The pad isolation insulating film 180 may fill pad isolation recesses. The pad isolation recesses may separate the neighboring storage pads 160.

The pad isolation insulating film 180 may include an insulating material and may electrically isolate the storage pads 160 from one another. For example, the pad isolation insulating film 180 may include, for example, at least one of a silicon oxide film, a silicon nitride film, a silicon oxynitride film, a silicon oxycarbonitride film, or a silicon carbonitride film, but example embodiments of the present disclosure are not limited thereto.

A lower peripheral interlayer insulating film 292 may be disposed on the substrate 100 of the peripheral area 24. The lower peripheral interlayer insulating film 292 may be disposed on the cell area isolation film 22.

The lower peripheral interlayer insulating film 292 may include an oxide-based insulating material. For example, the lower peripheral interlayer insulating film 292 may include silicon oxide.

An upper etching stop film 295 may be disposed on the upper surfaces of the storage pads 160 and the pad isolation insulating film 180. The upper etching stop film 295 may be disposed on the lower peripheral interlayer insulating film 292. The upper etching stop film 295 may include, for example, at least one of silicon nitride, silicon carbonitride, silicon oxycarbonitride, silicon boronitride, or silicon boron carbonitride.

The data storage patterns DSP may be disposed on the storage pads 160. The data storage patterns DSP are connected to the storage pads 160. Parts of the data storage patterns DSP may be disposed within the upper etching stop film 295.

For example, the data storage patterns DSP may be capacitors. The data storage patterns DSP include lower electrodes 191, capacitor dielectric films 192, and upper electrodes 193. For example, the upper electrodes 193 may be plate upper electrodes having a plate shape.

The lower electrodes 191 may be disposed on the storage pads 160. The lower electrodes 191 may have, for example, a pillar shape. The capacitor dielectric films 192 are disposed on the lower electrodes 191. The capacitor dielectric films 192 may be formed along the profile of the lower electrodes 191. The upper electrodes 193 are disposed on the capacitor dielectric films 192. The upper electrodes 193 may surround the outer sidewalls of the lower electrodes 191. The upper electrodes 193 are illustrated as being single films, but example embodiments of the present disclosure are not limited thereto. In some example embodiments, contrary to what is illustrated, the lower electrodes 191 may have a cylindrical shape with one side open.

The lower electrodes 191 and the upper electrodes 193 may each include, for example, at least one of a doped semiconductor material, conductive metal nitride (e.g., titanium nitride, tantalum nitride, niobium nitride, or tungsten nitride), metal (e.g., ruthenium, iridium, titanium, or tantalum), or conductive metal oxide (e.g., iridium oxide or niobium oxide), but example embodiments of the present disclosure are not limited thereto.

The capacitor dielectric films 192 may include, for example, at least one of silicon oxide, silicon nitride, silicon oxynitride, a high-k material, or a combination thereof, but example embodiments of the present disclosure are not limited thereto. The capacitor dielectric films 192 may include at least one of a ferroelectric material, an antiferroelectric material, or a paraelectric material. The capacitor dielectric films 192 may include, for example, one of a ferroelectric material, an antiferroelectric material, a paraelectric material, a combination of ferroelectric and antiferroelectric materials, a combination of ferroelectric and paraelectric materials, a combination of paraelectric and antiferroelectric materials, or a combination of ferroelectric, antiferroelectric, and paraelectric materials.

In the semiconductor memory device according to some example embodiments of the present disclosure, the capacitor dielectric films 192 may include a stacked film structure in which zirconium oxide, aluminum oxide, and zirconium oxide are sequentially stacked. In the semiconductor memory device according to some example embodiments of the present disclosure, the capacitor dielectric films 192 may each include a dielectric film containing hafnium (Hf).

In some example embodiments, the data storage patterns DSP may be variable resistance patterns that can switch between two resistance states due to electrical pulses applied to memory elements. For example, the data storage patterns DSP may include a phase-change material whose crystalline state changes according to the amount of current, a perovskite compound, a transition metal oxide, a magnetic material, a ferromagnetic material, or an antiferromagnetic material.

An upper peripheral interlayer insulating film 293 may be disposed on the upper etching stop film 295. The upper peripheral interlayer insulating film 293 may cover the sidewalls of the upper electrodes 193. The upper peripheral interlayer insulating film 293 may include, for example, at least one of a silicon oxide film, a silicon nitride film, a silicon oxynitride film, a silicon oxycarbonitride film, or a silicon carbonitride film, but example embodiments of the present disclosure are not limited thereto.

Peripheral connection lines 265 may be disposed on the cell area isolation film 22. The peripheral connection lines 265 may extend to the peripheral area 24. For example, the peripheral connection lines 265 may be connected to the gate electrodes and/or the source/drain regions of peripheral transistors disposed in the peripheral area 24. The peripheral connection lines 265 may connect the cell gate electrodes 112 and the peripheral transistors disposed in the peripheral area 24.

The cell gate plugs 261 may be disposed on the cell gate electrodes 112, respectively. The cell gate plugs 261 may be connected to the cell gate electrodes 112, respective/y. For example, the cell gate plugs 261 are electrically connected to the cell gate electrodes 112, respectively.

The cell gate plugs 261 is disposed between the cell gate electrode 112 and the peripheral connection lines 265. The cell gate plug 261 connects the cell gate electrode 112 and the peripheral connection line 265.

Referring to FIG. 9, the cell gate electrodes 112 may include first cell gate electrodes 112_1 and second cell gate electrodes 112_2, which are adjacent to the first cell gate electrodes 112_1 in the second direction DR2. The cell gate plugs 261 may include first cell gate plugs 261_1 and second cell gate plugs 261_2. The first cell gate plugs 261_1 may be connected to the first cell gate electrodes 112_1. The second cell gate plugs 261_2 may be connected to the second cell gate electrodes 112_2.

First sides of the first cell gate electrode 112_1 may be arranged in the second direction DR2 with first sides of the second cell gate electrodes 112_2. Second sides of the first cell gate electrodes 112_1 may be arranged in the second direction DR2 with second sides of the second cell gate electrodes 112_2. On the first sides of the first cell gate electrodes 112_1, the first cell gate plugs 261_1 may be connected to the first cell gate electrodes 112_1. On the second sides of the second cell gate electrodes 112_2, the second cell gate plugs 261_2 may be connected to the second cell gate electrodes 112_2.

In the semiconductor memory device according to some example embodiments of the present disclosure, the cell gate plugs 261 may not overlap the insertion cell gate films 112IN in the fourth direction DR4. The cell gate plugs 261 may be connected to the second regions 112R2 of the cell gate electrodes 112. The cell gate plugs 261 may contact the second regions 112R2 of the cell gate electrode 112.

Because the insertion cell gate films 112IN do not extend along the long sidewalls 115LSW of the cell gate trenches 115 in the second regions 112R2 of the cell gate electrodes 112, the cell gate plugs 261 may not overlap the insertion cell gate films 112IN in the second direction DR2.

The peripheral connection lines 265 and the cell gate plugs 261 may each include at least one of a doped semiconductor material, a conductive silicide compound, conductive metal nitride, conductive metal carbide, or metal. The peripheral connection lines 265 and the cell gate plugs 261 are illustrated as being different films, but example embodiments of the present disclosure are not limited thereto.

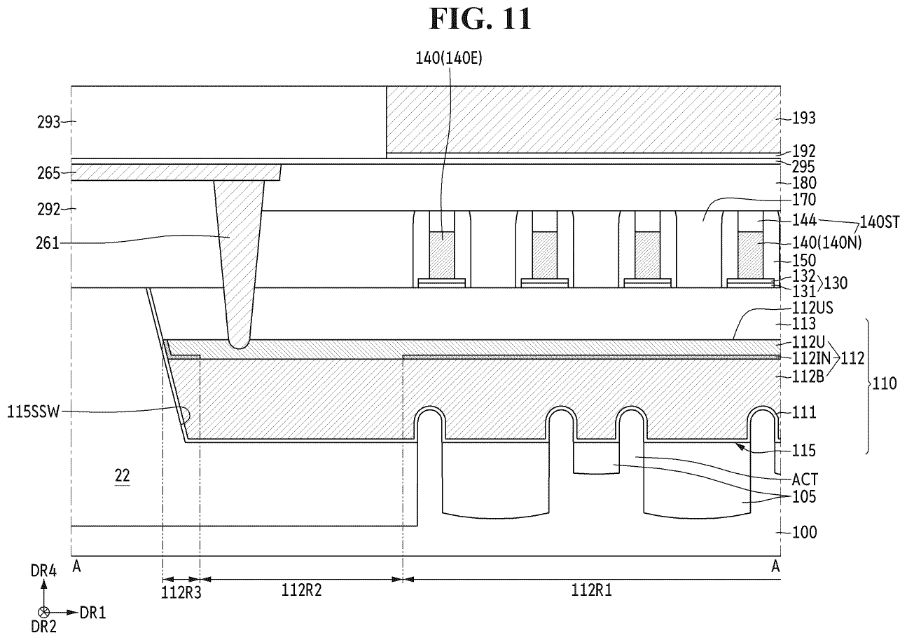

FIGS. 11 to 13 are diagrams illustrating semiconductor memory devices according to some embodiments. For convenience of explanation, the embodiments of FIGS. 11 to 13 will hereinafter be described, focusing mainly on the differences from what has been described above with reference to FIGS. 1 to 10.

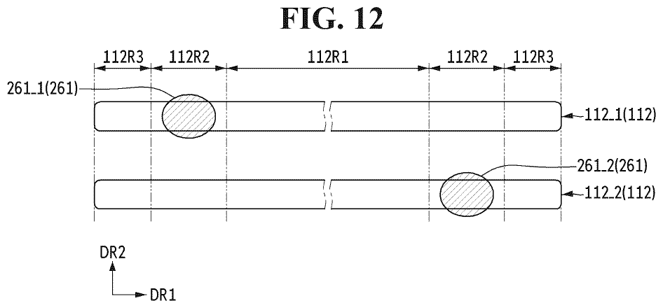

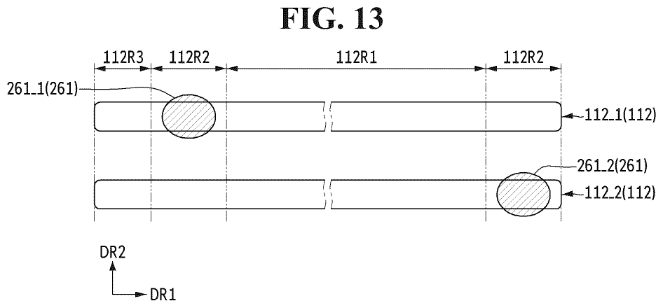

For reference, FIG. 11 is a cross-sectional view taken along line A-A of FIG. 4. FIGS. 12 and 13 are diagrams illustrating cell gate electrodes of FIG. 11.

Referring to FIGS. 11 to 13, in the semiconductor memory devices according to some embodiments of the present disclosure, each cell gate electrode 112 may further include third regions 112R3 that include an insertion cell gate film 112IN.

In each cell gate electrode 112, second regions 112R2 may be disposed between a first region 112R1 and the third regions 112R3. The first region 112R1, the second regions 112R2, and the third regions 112R3 may be arranged in a first direction DR1.

Referring to FIG. 12, the third regions 112R3 may be disposed on both sides of the first region 112R1.

The third regions 112R3 may include the ends of the corresponding cell gate electrode 112. Because the third regions 112R3 include the ends of the corresponding cell gate electrode 112, an insertion cell gate film 112IN may extend along a short sidewall 115SSW of a cell gate trench 115.

In FIG. 13, the third region 112R3 of the cell gate electrode may be disposed on one side of the first region 112R1 of the cell gate electrode and may not be disposed on the opposite side of the first region 112R1.

Each cell gate electrode 112 may include first and second ends spaced apart from each other in the first direction DR1. The first end of each cell gate electrode 112 may be included in the third region 112R3. Because the third region 112R3 is disposed at the first end of the corresponding cell gate electrode 112, an insertion cell gate film 112IN may be disposed on a short sidewall 115SSW of a cell gate trench 115 facing the first end of the corresponding cell gate electrode 112.

The second end of each cell gate electrode 112 may be included in second regions 112R2 of the corresponding cell gate electrode 112. Because the second regions 112R2 are disposed at the second end of the corresponding cell gate electrode 112, the insertion cell gate film 112IN may not be disposed on the short sidewall 115SSW of the cell gate trench 115 facing the second end of the corresponding cell gate electrode 112.

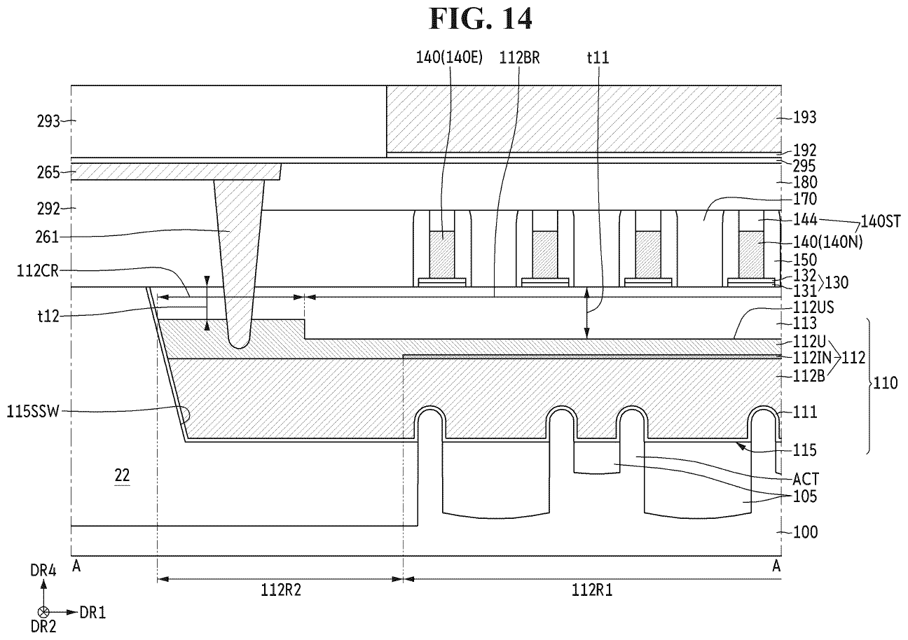

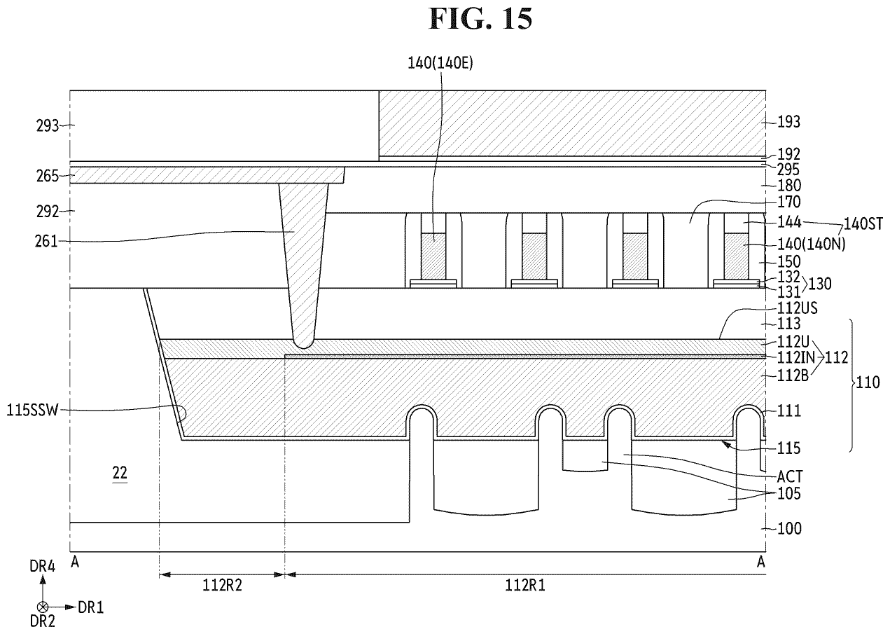

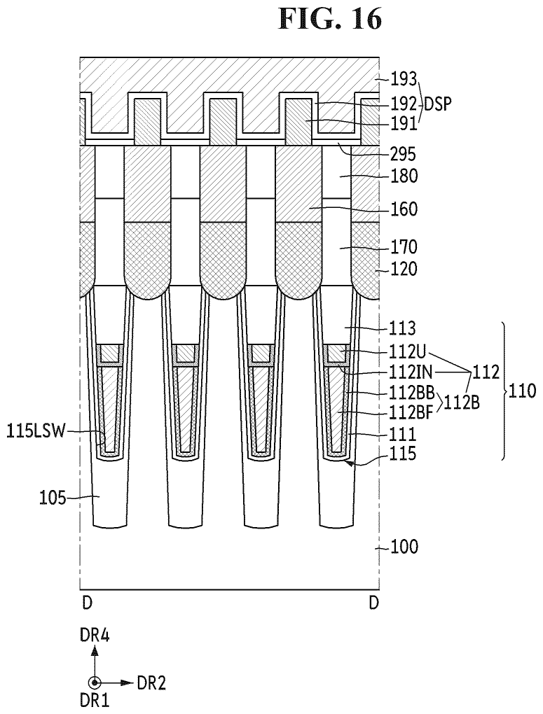

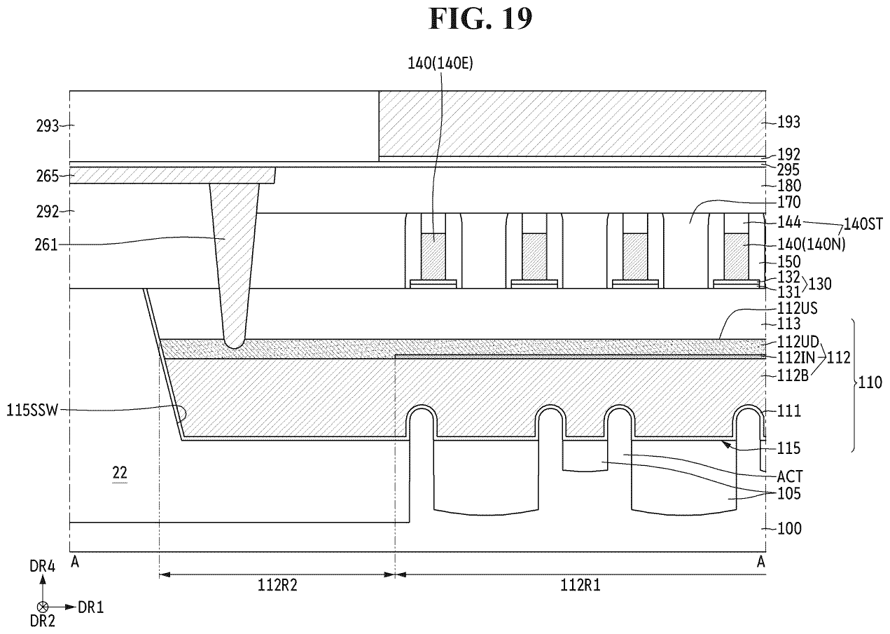

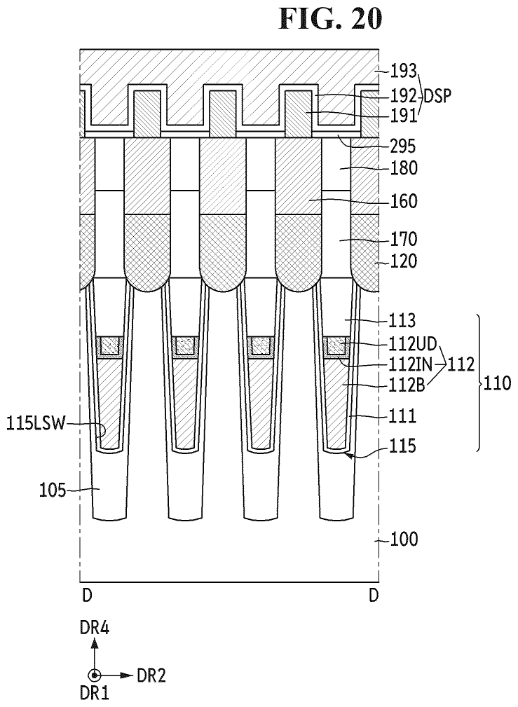

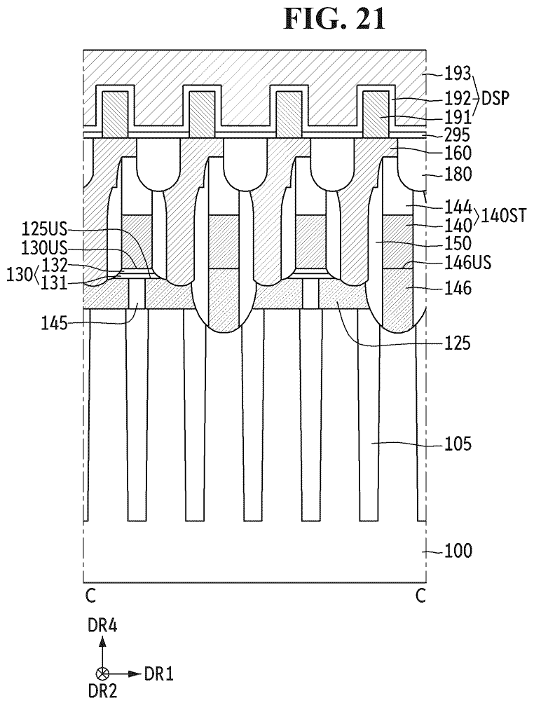

FIGS. 14 and 15 are diagrams illustrating semiconductor memory devices according to some example embodiments, respectively. FIGS. 16 to 18 are diagrams illustrating semiconductor memory devices according to some example embodiments, respectively. FIGS. 19 and 20 are diagrams illustrating a semiconductor memory device according to some example embodiments. FIG. 21 is a diagram illustrating a semiconductor memory device according to some example embodiments. For convenience of explanation, the embodiments of FIGS. 14 to 19 will hereinafter be described, focusing mainly on the differences from what has been described above with reference to FIGS. 1 to 10.

For reference, FIGS. 14, 15, and 19 are cross-sectional views taken along line A-A of FIG. 4. FIGS. 16 to 18 and 20 are cross-sectional views taken along line D-D of FIG. 4. FIG. 19 is a cross-sectional view taken along line C-C of FIG. 4.

Referring to FIG. 14, in the semiconductor memory device according to some example embodiments of the present disclosure, each cell gate electrode 112 may include a contact region 112CR and a body region 112BR.

The contact region 112CR may be located at the end of the corresponding cell gate electrode 112. The contact region 112CR and the body region 112BR may be arranged in a first direction DR1.

The contact region 112CR may be disposed on at least one side of the body region 112BR. For example, the contact region 112CR may be disposed on both sides of the body region 112BR. In another example, the contact region 112CR may be disposed only on one side of the body region 112BR.

The contact region 112CR may be disposed on a cell area isolation film 22. The contact region 112CR may overlap the cell area isolation film 22 in a fourth direction DR4.

A cell gate plug 261 may be disposed on the contact region 112CR. The cell gate plug 261 may be connected to the contact region 112CR.

An upper surface 112US of the corresponding cell gate electrode 112 may protrude more in the contact region 112CR than in the body region 112BR. Based on the bottom surface of the cell area isolation film 22, the upper surface 112US is higher in the contact region 112CR than in the body region 112BR.

For example, a thickness t11 of a cell gate capping pattern 113 on the body region 112BR is greater than a thickness t12 of the cell gate capping pattern 113 on the contact region 112CR.

At least a portion of a second region 112R2 of the corresponding cell gate electrode 112 may overlap the contact region 112CR in the fourth direction DR4. In other words, the contact region 112CR may include at least a portion of the second region 112R2. An insertion cell gate film 112IN is illustrated as not overlapping the contact region in the fourth direction DR4, but example embodiments of the present disclosure are not limited thereto.

Referring to FIG. 15, in the semiconductor memory device according to some example embodiments of the present disclosure, a cell gate plug 261 may be disposed on an insertion cell gate film 112IN.

The cell gate plug 261 may overlap the insertion cell gate film 112IN in a fourth direction DR4. Although not illustrated, the cell gate plug 261 may overlap the insertion cell gate film 112IN in a second direction DR2.

Referring to FIGS. 16 to 18, in the semiconductor memory devices according to some example embodiments of the present disclosure, a lower cell gate electrode 112B or an upper cell gate electrode 112U may have a multi-conductive film structure that includes a plurality of conductive films.

Referring to FIG. 16, the lower cell gate electrode 112B may include a lower cell gate barrier film 112BB and a lower cell gate filling film 112BF. The lower cell gate filling film 112BF may be disposed on the lower cell gate barrier film 112BB.

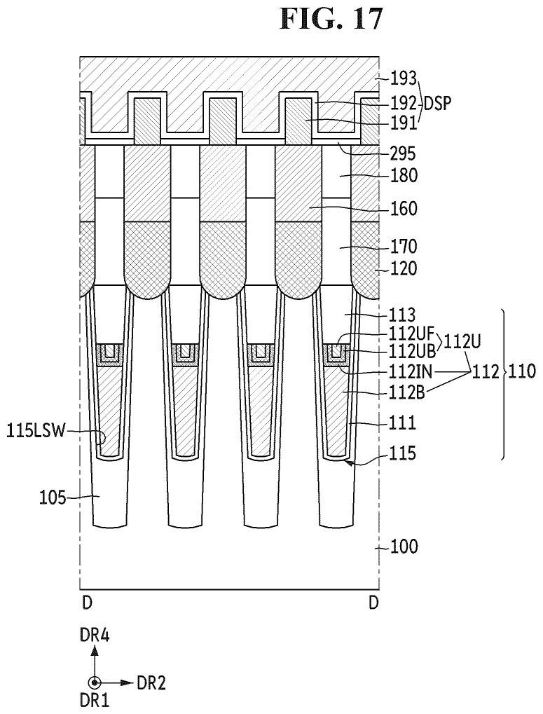

Referring to FIG. 17, an upper cell gate electrode 112U may include an upper cell gate barrier film 112UB and an upper cell gate filling film 112UF. The upper cell gate barrier film 112UB and the upper cell gate filling film 112UF may be sequentially disposed on an insertion cell gate film 112IN.

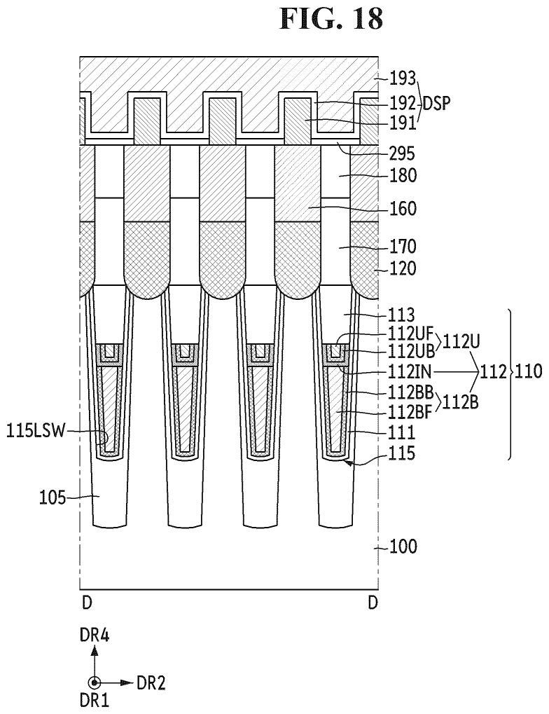

Referring to FIG. 18, a lower cell gate electrode 112B may include a lower cell gate barrier film 112BB and a lower cell gate filling film 112BF. An upper cell gate electrode 112U may include an upper cell gate barrier film 112UB and an upper cell gate filling film 112UF.

Each of the lower cell gate barrier film 112BB, the lower cell gate filling film 112BF, the upper cell gate barrier film 112UB, and the upper cell gate filling film 112UF may include, for example, at least one of conductive metal nitride, conductive metal silicon nitride, metal carbonitride, conductive metal silicide, conductive metal oxide, a 2D material, or metal. Each of the lower cell gate barrier film 112BB, the lower cell gate filling film 112BF, the upper cell gate barrier film 112UB, and the upper cell gate filling film 112UF may include at least one of TiN, W, or Mo, but example embodiments of the present disclosure are not limited thereto.

Referring to FIGS. 19 and 20, in the semiconductor memory device according to some example embodiments of the present disclosure, each cell gate electrode 112 may include a lower cell gate electrode 112B, an insertion cell gate film 112IN, and an upper cell gate doping electrode 112UD, which are stacked in a fourth direction DR4.

The insertion cell gate film 112IN may be positioned between the lower cell gate electrode 112B and the upper cell gate doping electrode 112UD.

The upper cell gate doping electrode 112UD includes a conductive material and may include, for example, titanium nitride or molybdenum. Unlike what is illustrated, the upper cell gate doping electrode 112UD may have a multi-film structure as illustrated in FIG. 17.

The upper cell gate doping electrode 112UD may further include a doped impurity element. The upper cell gate doping electrode 112UD may include a conductive material doped with an impurity element. The impurity element may include, for example, at least one of phosphorus (P), arsenic (As), nitrogen (N), or germanium (Ge).

Due to the impurity element doped in the upper cell gate doping electrode 112UD, a dipole may be formed at the interface between the insertion cell gate film 112IN and the cell gate insulating film 111. The dipole between the insertion cell gate film 112IN and the cell gate insulating film 111 may adjust the work function of the gate electrode of a transistor. As a dipole is formed between the upper cell gate doping electrode 112UD and the cell gate insulating film 111, the cell gate electrode 112, which is the gate electrode of a transistor, may have a multi-work function structure. Thus, the gate-induced drain leakage (GIDL) characteristic of the transistor may be improved (e.g., reduced).

Referring to FIG. 21, in the semiconductor memory device according to some example embodiments of the present disclosure, storage contacts 125 may be disposed on a substrate 100 and a cell element isolation film 105.

The storage contacts 125 may be disposed on the upper surface of the cell element isolation film 105. The lower surfaces of the storage contacts 125 may be disposed on the upper surface of the cell element isolation film 105. The storage contacts 125 may contact the upper surface of the cell element isolation film 105.

Based on the upper surface of the cell element isolation film 105, upper surfaces 125US of the storage contacts 125 may be lower than upper surfaces 146US of bitline contacts 146. Based on the upper surface of the cell element isolation film 105, the upper surfaces 125US of the storage contacts 125 may be lower than the lower surfaces of cell conductive lines 140.

Contact isolation patterns 145 may separate the storage contacts 125 that are adjacent in a first direction DR1. When the storage contacts 125 include first storage contacts and second storage contacts that are spaced apart from the first storage contacts in the first direction DR1, the contact isolation patterns 145 may separate the first storage contacts and the second storage contacts in the first direction DR1. Although not illustrated, the contact isolation patterns 145 may also separate storage contacts 120 that are adjacent in a second direction DR2.

Cell line spacers 150 may be disposed on the upper surfaces 125US of the storage contacts 125. Cell insulating films 130 may cover the upper surfaces 125US of the storage contacts 125. When the storage contacts 125 include the first storage contacts and the second storage contacts that are spaced apart from the first storage contacts in the first direction DR1, the cell insulating films 130 may cover the upper surfaces of the first storage contacts and the upper surfaces of the second storage contacts.

Upper surfaces 130US of the cell insulating films 130 may be on the same plane as the upper surfaces 146US of the bitline contacts 146. That is, based on the upper surface of the cell element isolation film 105, the height of the upper surfaces 130US of the cell insulating films 130 may be the same as the height of the upper surfaces 146US of the bitline contacts 146. The cell conductive lines 140 may be disposed on the upper surfaces 130US of the cell insulating films 130.

The contact isolation patterns 145 may include, for example, at least one of silicon nitride, silicon oxynitride, silicon oxide, silicon carbonitride, silicon oxycarbonitride, or a combination thereof. The width of the cell insulating films 130 in the first direction DR1 is illustrated as decreasing away from the substrate 100, but example embodiments of the present disclosure are not limited thereto.

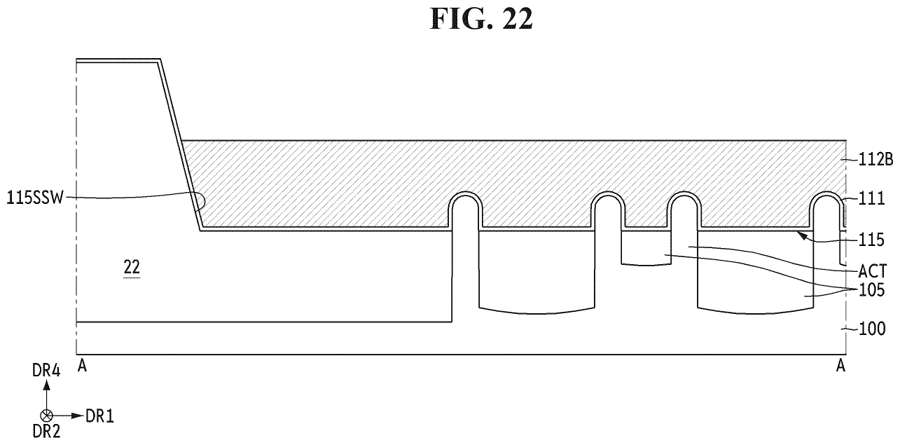

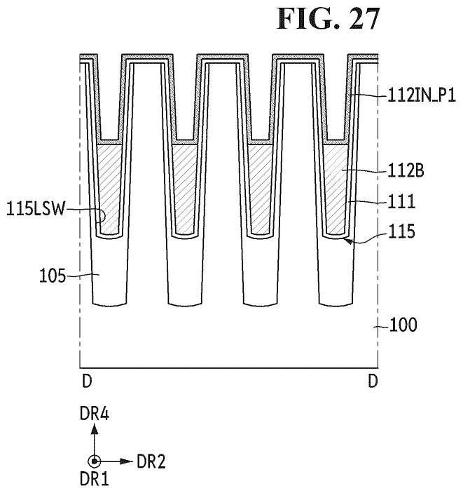

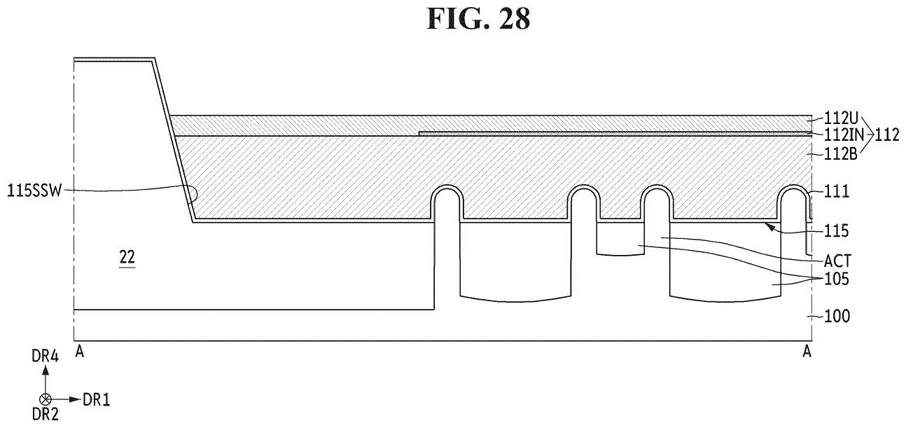

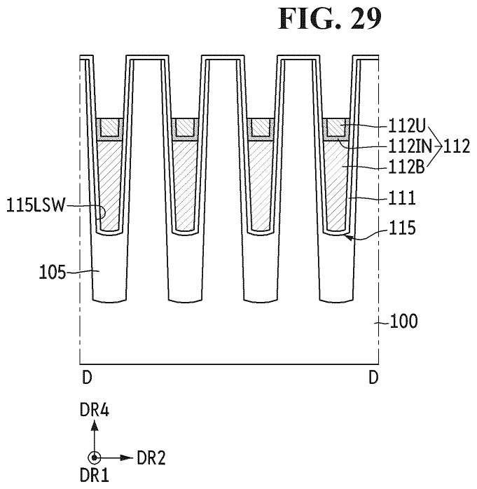

FIGS. 22 to 30 are diagrams of intermediate structures corresponding to intermediate steps of a method for fabricating a semiconductor memory device according to some example embodiments.

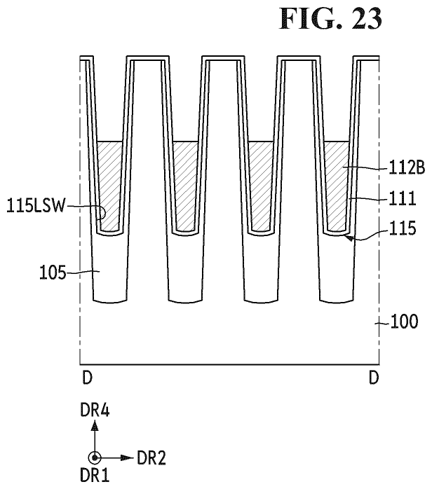

Referring to FIGS. 22 and 23, a cell area isolation film 22 and a cell element isolation film 105 may be formed in a substrate 100.

The cell area isolation film 22 may be formed to define a cell area 20 (in FIG. 1) and a peripheral area 24 (in FIG. 1). The cell element isolation film 105 may define cell active areas ACT.

Thereafter, cell gate trenches 115 may be formed in the cell area 20 and the cell area isolation film 22. The cell gate trenches 115 may extend in a first direction DR1.

A cell gate insulating film 111 may be formed along the profile of the cell gate trenches 115. The cell gate insulating film 111 may be formed along long sidewalls 115LSW, short sidewalls 115SSW, and the bottom surfaces of the cell gate trenches 115. The cell gate insulating film 111 may be formed along the upper surface of the substrate 100 and the upper surface of the cell area isolation film 22.

Thereafter, lower cell gate electrodes 112B may be formed on the cell gate insulating film 111.

For example, a lower cell gate film may be formed on the cell gate insulating film 111. The lower cell gate film may fill the cell gate trenches 115. By etching portions of the lower cell gate film, the lower cell gate electrodes 112B may be formed within the cell gate trenches 115.

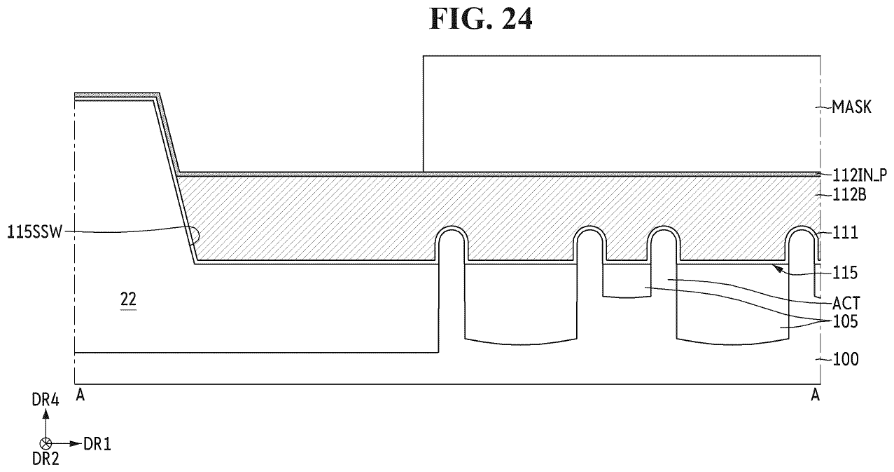

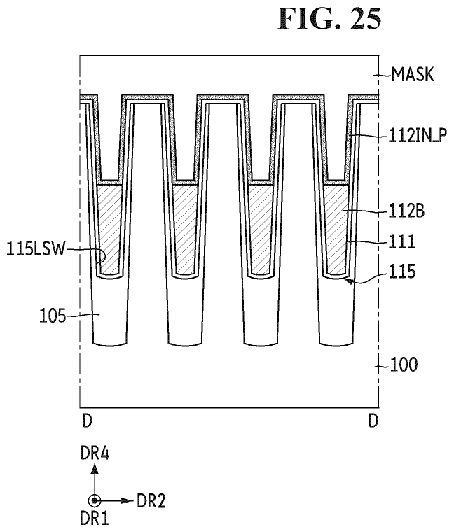

Referring to FIGS. 24 and 25, a first pre-insertion gate film 112IN_P may be formed on the lower cell gate electrodes 112B. The first pre-insertion gate film 112IN_P may be formed along the upper surface of the lower cell gate electrode 112B. The first pre-insertion gate film 112IN_P may be formed along the long sidewalls 115LSW and the short sidewalls 115SSW of the cell gate trenches 115. The first pre-insertion gate film 112IN_P may be formed along the upper surface of the substrate 100 and the upper surface of the cell area isolation film 22.

The first pre-insertion gate film 112IN_P may include La. For example, the first pre-insertion gate film 112IN_P may include lanthanum oxide. The first pre-insertion gate film 112IN_P may be formed using atomic layer deposition (ALD) or chemical vapor deposition (CVD), but example embodiments of the present disclosure are not limited thereto.

Thereafter, a mask pattern MASK may be formed on the first pre-insertion gate film 112IN_P. The mask pattern MASK may expose portions of the first pre-insertion gate film 112IN_P. For example, in a cross-sectional view such as FIG. 22, the mask pattern MASK may expose the first pre-insertion gate film 112IN_P on the upper surface of the cell area isolation film 22.

Depending on the shape of the mask pattern MASK, the patterned shape of the first pre-insertion gate film 112IN_P may vary. That is, contrary to what is illustrated, in a cross-sectional view such as FIG. 22, the mask pattern MASK may not expose the first pre-insertion gate film 112IN_P on the upper surface of the cell area isolation film 22. The mask pattern MASK may only expose portions of the first pre-insertion gate film 112IN_P formed along the upper surfaces of the lower cell gate electrodes 112B.

Referring to FIGS. 24 to 27, portions of the first pre-insertion gate film 112IN_P may be removed using the mask pattern MASK as a mask.

In this manner, a second pre-insertion gate film 112IN_P1 may be formed on the upper surfaces of the lower cell gate electrodes 112B.

Thereafter, the mask pattern MASK is removed.

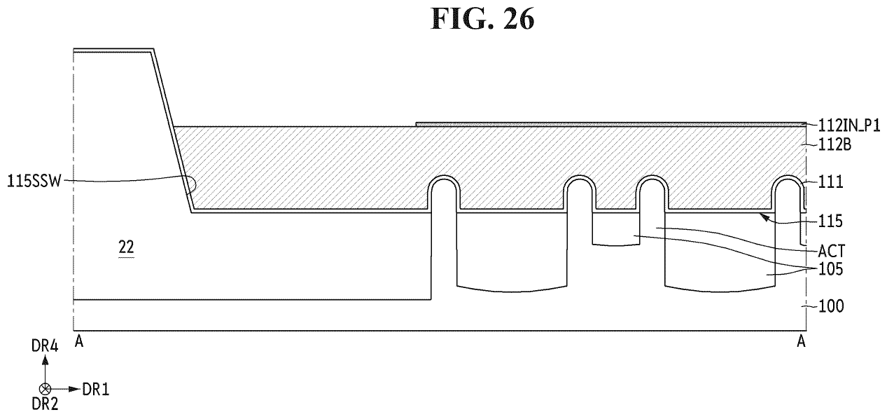

Referring to FIGS. 26 to 29, an upper cell gate film may be formed on the second pre-insertion gate film 112IN_P1.

The upper cell gate film may fill the cell gate trenches 115 that remain after the formation of the lower cell gate electrodes 112B and the second pre-insertion gate film 112IN_P1.

Thereafter, by etching portions of the upper cell gate film, upper cell gate electrodes 112U may be formed within the cell gate trenches 115. In one example, during the formation of the upper cell gate electrodes 112U, portions of the second pre-insertion gate film 112IN_P1 may be removed to form insertion cell gate films 112IN. In another example, after the formation of the upper cell gate electrodes 112U, exposed portions of the second pre-insertion gate film 112IN_P1 may be removed to form the insertion cell gate films 112IN.

The upper cell gate electrodes 112U and the insertion cell gate films 112IN may be formed so that cell gate electrodes 112 may formed within the cell gate trenches 115.

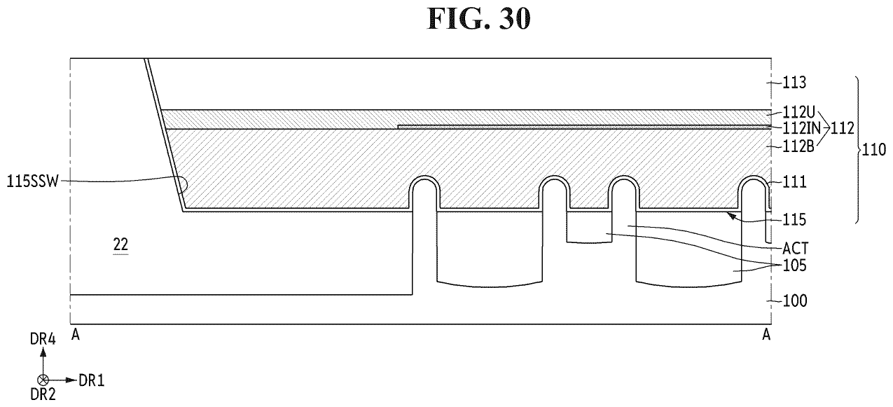

Referring to FIG. 30, cell gate capping patterns 113 may be formed on the cell gate electrodes 112.

The cell gate capping patterns 113 may be formed within the cell gate trenches 115. The cell gate capping patterns 113 may fill the cell gate trenches 115. In this manner, cell gate structures 110 may be formed.

During the formation of the cell gate capping patterns 113, the cell gate insulating films 111 on the upper surface of the substrate 100 and the upper surface of the cell area isolation film 22 may be removed. In some example embodiments, contrary to what is illustrated, during the formation of the cell gate capping patterns 113, the cell gate insulating films 111 on the upper surface of the substrate 100 and the upper surface of the cell area isolation film 22 may not be removed.

In the method of manufacturing a semiconductor memory device according to some example embodiments of the present disclosure, before the formation of the cell gate capping pattern 113, an impurity implantation process for injecting an impurity element into the upper cell gate electrodes 112U may further be performed. Through this, upper cell gate doping electrodes 112UD may be formed, as described with reference to FIGS. 19 and 20. For example, the impurity implantation process may include an ion implantation process, but example embodiments of the present disclosure are not limited thereto.

Thereafter, referring to FIGS. 5 to 8, bitline structures 140ST may be formed on the cell gate structures 110. Data storage patterns DSP may be formed on the bitline structures 140ST.

In one example, during the manufacture of the semiconductor memory device, the insertion cell gate films 112IN may remain as LaO. In another example, portions of the first pre-insertion gate film 112IN_P or the second pre-insertion gate film 112IN_P1 may change to La-doped metal or a La-doped metal compound. The La included in the lanthanum oxide may diffuse into the lower cell gate electrodes 112B. In another example, during the formation of the upper insertion gate electrodes 112U, the insertion cell gate films 112IN may change to La-doped metal or a La-doped metal compound. The La included in the lanthanum oxide may diffuse into the lower cell gate electrodes 112B and/or the upper cell gate electrodes 112U. In yet another example, after the formation of the upper insertion gate electrodes 112U, the insertion cell gate films 112IN may change to La-doped metal or a La-doped metal compound.

Although some example embodiments of the present disclosure have been described with reference to the accompanying drawings, a person skilled in the art may appreciate that the present disclosure may be practiced in other concrete forms without changing the technical spirit or essential characteristics of the present disclosure. Therefore, it should be appreciated that the example embodiments as described above are not restrictive but illustrative in all respects.

1. A semiconductor memory device comprising:
a substrate including a cell area and a peripheral area around the cell area;
a cell area isolation film within the substrate and separating the cell area and the peripheral area;
a cell gate structure within the cell area and the cell area isolation film, the cell gate structure including a cell gate electrode extending in a first direction; and
a cell gate plug on and connected to the cell gate electrode,
wherein
the cell gate electrode includes a lower cell gate electrode and an upper cell gate electrode stacked in a second direction, and an insertion cell gate film between the lower cell gate electrode and the upper cell gate electrode,
the insertion cell gate film includes lanthanum (La),
the cell gate electrode includes a first region and a second region arranged in the first direction,
the first region of the cell gate electrode includes the insertion cell gate film, and
the second region of the cell gate electrode does not include the insertion cell gate film.

2. The semiconductor memory device of claim 1, wherein the second region of the cell gate electrode overlaps the cell area isolation film in the second direction.

3. The semiconductor memory device of claim 1, wherein the cell gate plug contacts the second region of the cell gate electrode.

4. The semiconductor memory device of claim 1, wherein
the cell gate electrode further includes a third region,
the second region of the cell gate electrode is between the first region and the third region of the cell gate electrode, and
the third region of the cell gate electrode includes the insertion cell gate film.

5. The semiconductor memory device of claim 1, wherein
the cell gate structure further includes a cell gate capping pattern on the cell gate electrode,
the cell gate electrode includes a body region and a contact region,
the contact region of the cell gate electrode is on the cell area isolation film,
the cell gate plug is connected to the contact region of the cell gate electrode, and
a thickness of the cell gate capping pattern on the body region of the cell gate electrode is greater than a thickness of the cell gate capping pattern on the contact region of the cell gate electrode.

6. The semiconductor memory device of claim 5, wherein at least a portion of the second region of the cell gate electrode overlaps the contact region of the cell gate electrode in the second direction.

7. The semiconductor memory device of claim 1, wherein
the cell gate structure further includes a cell gate capping pattern on the cell gate electrode,
the cell gate capping pattern includes an insulating material, and
the cell gate structure does not include a semiconductor material film between the cell gate capping pattern and the cell gate electrode.

8. The semiconductor memory device of claim 1, wherein the insertion cell gate film includes lanthanum oxide.

9. The semiconductor memory device of claim 1, wherein
the insertion cell gate film includes lanthanum-doped metal or a lanthanum-doped metal compound, and
the lanthanum-doped metal compound includes at least one of metal nitride, metal oxynitride, or metal oxide.

10. The semiconductor memory device of claim 1, wherein
the upper cell gate electrode further includes an impurity element, and
the impurity element includes at least one of phosphorus (P), arsenic (As), nitrogen (N), or germanium (Ge).

11. A semiconductor memory device comprising:
a substrate including a cell area and a peripheral area around the cell area;
a cell area isolation film within the substrate and separating the cell area and the peripheral area;
a cell gate structure within the cell area and the cell area isolation film, the cell gate structure including a cell gate electrode extending in a first direction; and
a cell gate plug on and connected to the cell gate electrode,
wherein
the cell gate electrode includes a lower cell gate electrode and an upper cell gate electrode stacked in a second direction, and an insertion cell gate film between the lower cell gate electrode and the upper cell gate electrode,
the insertion cell gate film includes lanthanum (La), and
the cell gate plug does not overlap the insertion cell gate film in the second direction.

12. The semiconductor memory device of claim 11, wherein
the cell gate electrode includes a first region and a second region arranged in the first direction,
the first region of the cell gate electrode includes the insertion cell gate film, the second region of the cell gate electrode does not include the insertion cell gate film, and
at least a portion of the second region overlaps the cell area isolation film in the second direction.

13. The semiconductor memory device of claim 12, wherein
the cell gate electrode further includes a third region,
the second region of the cell gate electrode is between the first region and the third region of the cell gate electrode, and
the third region of the cell gate electrode includes the insertion cell gate film.

14. The semiconductor memory device of claim 11, wherein
the cell gate structure further includes a cell gate capping pattern on the cell gate electrode,
the cell gate electrode includes a body region and a contact region,
the contact region of the cell gate electrode is on the cell area isolation film,
the cell gate plug is connected to the contact region of the cell gate electrode, and
a thickness of the cell gate capping pattern on the body region of the cell gate electrode is greater than a thickness of the cell gate capping pattern on the contact region of the cell gate electrode.

15. The semiconductor memory device of claim 11, wherein
the cell gate structure further includes a cell gate capping pattern on the cell gate electrode,
the cell gate capping pattern includes an insulating material, and
the cell gate structure does not include a semiconductor material film between the cell gate capping pattern and the cell gate electrode.

16. The semiconductor memory device of claim 11, wherein the cell gate plug does not overlap the insertion cell gate film in a third direction perpendicular to the first and second directions.

17. The semiconductor memory device of claim 11, wherein
the insertion cell gate film includes at least one of lanthanum oxide, metal doped with La, or a metal compound doped with La, and
the metal compound includes at least one of metal nitride, metal oxynitride, or metal oxide.

18. A semiconductor memory device comprising:
a substrate including a cell area and a peripheral area around the cell area;
a cell area isolation film within the substrate and separating the cell area and the peripheral area;
a cell gate structure including a cell gate trench extending in a first direction within the cell area and the cell area isolation film and a cell gate electrode within the cell gate trench; and
a cell gate plug on and connected to the cell gate electrode,
wherein
the cell gate trench includes long sidewalls extending in the first direction and short sidewalls extending in a second direction perpendicular to the first direction,
the cell gate electrode includes a lower cell gate electrode and an upper cell gate electrode stacked in a third direction perpendicular to the first and second directions, and an insertion cell gate film between the lower cell gate electrode and the upper cell gate electrode,
the insertion cell gate film includes lanthanum (La), and
the insertion cell gate film is on the long sidewalls of the cell gate trench and not on the short sidewalls of the cell gate trench.

19. The semiconductor memory device of claim 18, wherein the cell gate plug does not overlap the insertion cell gate film in the third direction.

20. The semiconductor memory device of claim 18, wherein
the cell gate structure further includes a cell gate capping pattern on the cell gate electrode,
the cell gate capping pattern includes an insulating material, and
the cell gate structure does not include a semiconductor material film between the cell gate capping pattern and the cell gate electrode.

21-23. (canceled)
